(19) United States
(12) Patent Application Publication
(10) Pub. No.: US 2012/0243212 A1
(43) Pub. Date: Sep. 27, 2012

(54) PORTABLE AND BENDABLE UTILITY LIGHT

(76) Inventors: David Smith, Roseville, CA (US); Steven Rosier, Sacramento, CA (US); Gary Quigley, Loomis, CA (US)

(21) Appl. No.: 13/053,915

(22) Filed: Mar. 22, 2011

(51) Int. Cl. F21L 4/08; H05K 3/30; F21L 4/00

(52) U.S. Cl. 362/183; 362/189; 29/832

(57) ABSTRACT

A portable and bendable utility light is disclosed. Example embodiments include a body fabricated from a flexible non-metallic material, the body including a spine and a handle, the spine including a plurality of articulated light cells and corresponding radiused gaps between each light cell to facilitate bending of the spine in a plurality of directions; and an electrical assembly enveloped within the body, the electrical assembly including a conducting plane, a plurality of light emitting diodes (LEDs) in electrical connection with the conducting plane and positioned within each of the plurality of articulated light cells, as power source in electrical connection with the conducting plane, and a switch in electrical connection with the power source and the conducting plane.

### COPYRIGHT NOTICE

A portion of the disclosure of this patent document contains material that is subject to copyright protection. The copyright owner has no objection to the facsimile reproduction by anyone of the patent document or the patent disclosure, as it appears in the Patent and Trademark Office patent files or records, but otherwise reserves all copyright rights whatsoever. The following notice applies to the disclosure herein and to the drawings that form a part of this document: Copyright 2010-2011, David Smith, Steven Rosier, and Gary Quigley; All Rights Reserved.

### BACKGROUND

1. Technical Field

This disclosure relates to utility lights, more specifically, to a portable and bendable utility light.

2. Related Art

Light emitting diodes (LEDs) are useful as a basic lighting source in a variety of forms, such as outdoor signage and signaling, replacement light bulbs, or decorative lighting, for several reasons. First, LEDs have a longer lifespan than all other standard light sources, particularly common, fluorescent and incandescent sources. Second, LEDs have several favorable physical properties, including ruggedness, cool operation, ability to op rate under a wide temperature variation, and safe low-voltage power requirements. Third, newer, more sophisticated doping technologies, increase LED efficiency measured as light output versus power consumed, with efficiencies on the order of ten times that of incandescent lighting. Fourth, LEDs are becoming increasingly cost effective with the increase in applications and resulting volume demand.

LEDs have been used in various types of utility lights. Some examples of utility lights that have been the subject of patent filings include the examples provided below.

U.S. Patent Publication No. 2005/0018435 describes a portable battery utility light comprising light-emitting diodes on a casing pivotally mounted on a body containing battery and circuitry and system to power.

U.S. Pat. No. 5,404,282 describes an LED module for providing a source of illumination comprises a plurality of LED lamps each having an anode lead and a cathode lead for providing electrical and mechanical connection. The anode lead of each LED lamp is connected to an anode bus bar and the cathode lead of each LED lamp is connected to a cathode bus bar by solderless connection. The bus bars and the leads of each LED lamp may be integral with each other. Alternatively, the bus bars and leads may be non-integral with each other, connected by an interlocking interaction or interference tit between approximately complementary portions of each lead and bus bar. The LED module may accommodate serial electrical interconnection with other LED modules, it may be shaped according to the particular contour or design of an accommodating light assembly, and it may comprise LED lamps placed at arbitrary positions to achieve a predetermined degree of illumination.

U.S. Pat. No. 6,072,280 describes an LED light string employing a plurality of LEDs wired in a series-parallel block. Further, each series-parallel block may be coupled in parallel, the parallel connection coupled across a supply voltage through an electrical interface, LEDs of the light string may comprise either a single color LED or an LED including multiple sub-dies, each sub-die of a different color. LED series-parallel blocks of the light string may be operated in continuous, periodic or pseudo-random state. The LED light string may provide polarized connectors to couple LED light strings end-to-end and in parallel with the supply voltage. The electrical interface may have one or more parallel outputs and a switch so as to operate multiple LED light strings in continuous, periodic or pseudo-random states. The LED light string may be adapted so as to employ LEDs of different drive voltages in each series section of the series-parallel block. Fiber optic bundles may be coupled to individual LEDs to diffuse LED light output in a predetermined manner.

However, conventional utility lights do not provide a structure that is both resilient to pressure, temperature, and moisture, yet bendable to accommodate lighting in a variety of applications.

Thus, a portable and bendable utility light is needed.

### BRIEF DESCRIPTION OF THE DRAWINGS

Embodiments illustrated by way of example and not limitation in the figures of the accompanying drawings, in which:

FIG. 1 is a to view of the portable and bendable utility light, in accordance with an example embodiment;

FIG. 2 is a right side view of the portable and bendable utility light, as shown in the example embodiment of FIG. 1;

FIG. 3 is a bottom view of the portable and bendable utility light, as shown in the example embodiment of FIG. 1;

FIG. 4 illustrates the joints between each light cell, in accordance with an example embodiment;

FIG. 5 illustrates the handle portion of the portable and bendable utility light, in accordance with an example embodiment;

FIG. 6 illustrates a top view of the portable and bendable utility light when the lights are illuminated, in accordance with an example embodiment;

FIG. 7 illustrates a top view of the portable and bendable utility light when the utility light is bent in a first direction, in accordance with an example embodiment;

FIG. 8 illustrates a side view of the portable and bendable utility light when the utility light is bent in a second direction, in accordance with an example embodiment;

FIG. 9 illustrates a side view of the portable and bendable utility light when the utility light is bent in a third direction, in accordance with an example embodiment;

FIG. 10 illustrates a perspective view of the portable and bendable utility light when the utility light is bent in a first and a second direction, in accordance with an example embodiment;

FIG. 11 illustrates a die press with a die used to cut conducting layers from a sheet of conductive material and to cut a non-conducting layer from a sheet of non-conductive material, in accordance with an example embodiment;

FIG. 12 illustrates how two electrical conducting layers and a non-conducting layer are stacked or sandwiched together to form a three-layered conducting plane, in accordance with an example embodiment;

FIG. 13 illustrates how the layered conducting plane can be modified to include a depression at each joint between each of the plurality of light cells, in accordance with an example embodiment;

FIG. 14 illustrates a completed conducting plane of an example embodiment;

FIGS. 15-17 illustrate how a plurality of LEDs can be electrically attached to the conducting plane at a plurality of holes, in accordance with an example embodiment;

FIGS. 18-19 illustrate how the battery and the switch are electrically connected to the conducting plane with a plurality of LEDs attached thereto, in accordance with an example embodiment;

FIG. 20 illustrates the application of the polyurethane to an electrical assembly positioned in a mold, in an example embodiment;

FIG. 21 is a top view of an alternative implementation of the portable and bendable utility light, in accordance with an example embodiment; and

FIG. 22 is flow diagram illustrating a process for constructing the portable and bendable utility light, in accordance with an example embodiment;

### DETAILED DESCRIPTION

A portable and bendable utility light is disclosed. In the following description, numerous specific details are set forth. However, it is understood that embodiments may be practiced without these specific details. In other instances, well-known processes, structures and techniques have not been shown in detail in order not to obscure the clarity of this description. Various embodiments are described below in connection with the figures provided herein.

In the various embodiments described herein, a portable and bendable utility light delivers portable illumination in a nearly indestructible package. The portable and bendable utility light has a flexible body allowing delivery of light in a straight or curved manner. No other conventional utility lighting tool can perform this task. The portable and bendable utility light of various embodiments can be submitted to massive pressures, temperatures, and forceful blows from heavy or sharp objects without failure. The portable and bendable utility light can endure these forces at limits far above any other conventional utility light. No conventional lighting tool cart sustain the punishment the portable and bendable utility light described herein can endure. The portable and bendable utility light of particular embodiments can also be configured per customer request using and/or modifying some of the particular aspects of the body and electrical assembly described in more detail below.

### Description of an Example Embodiment

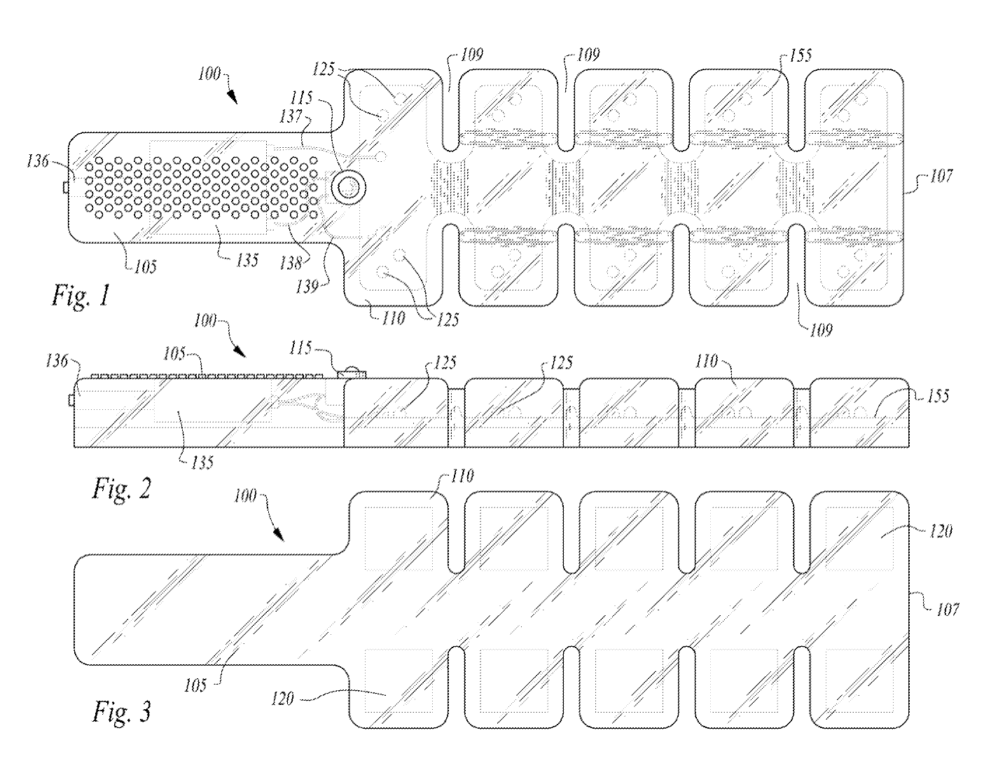

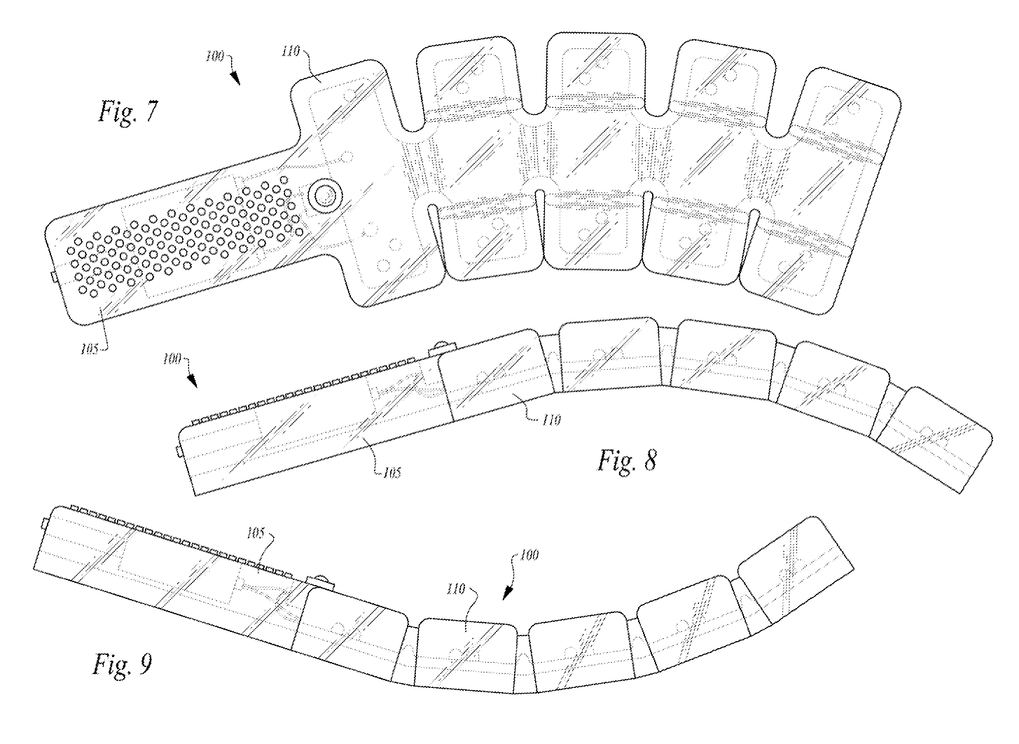

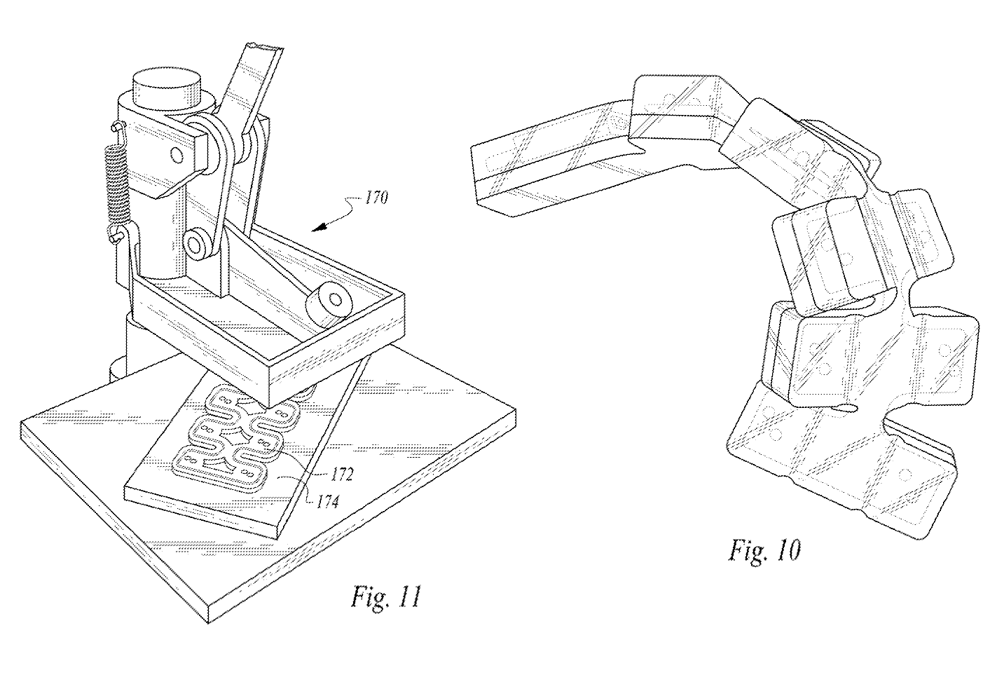

Referring now to FIG. 1, a particular embodiment of the portable bendable utility light is shown. The particular embodiment of the portable bendable utility light 100 includes a body having a handle 105 and a spine 107. The spine 107 includes a plurality of light cells 110 in an articulated arrangement. Each light cell includes a plurality of LEDs 125 embedded therein. The spine 107 connects each of the light cells 110 to a handle 105 of the utility light 100. The spine 107 allows for clean electrical tracing through the center of the utility light 100 as described in more detail below. The central location of the spine 107 and the symmetrical positioning of the light cells 110 provide balance and a positive weight in the hands of the user. The articulated arrangement of the light cells 110 on the spine 107 enable the spine 107 to be bent or twisted in a plurality of directions. For example, see FIGS. 7 through 10.

As shown in FIGS. 7 through 10, the overall articulated spine design of a particular embodiment provides flexible configuration of the light cells 110 on the spine 107. The utility light 100 can be bent in various directions to accommodate tight-fitting work areas. The utility light 100 can be bent in various directions also to focus or diffuse the light emitted from the LEDs 125. As shown in FIGS. 1-10, ridges, relief cuts, valleys, and finger-like appendages allow the utility light 100 to move as the operator desires. Radiused gaps 109 between light cells 110 facilitate bending and rotation of the spine 107 while acting as a mechanical limiting device when the utility light 100 is bent into an arc. These gaps 109 also spread and limit stresses placed on internal electrical components, yet still allow for precise bending and twisting. The specific section widths of the light cells 110 provide an area for placement of a plurality of LEDs 125 and yet allow for two or three dimensional movement when the utility light 100 is bent or twisted. These light cells 110 serve to limit the bending and therefore protect the utility light 100 from achieving a bending radius the material of the utility light 100 cannot sustain. These features also allow utility light 100 to be attached to concave and convex surfaces. The articulated spine design also provides the ability to illuminate three dimensional surfaces by rotating the utility light 100 through the center. The handle 105 provides a non-slip grip to manipulate the utility light 100 as needed. Handle 105 is multi-surfaced and can feature a signature grip in a particular embodiment.

As described in more detail below, the utility light 100 of one embodiment is fabricated from a combination of inter-connected electrical components captured in a body comprising as flexible formed non-metallic material (e.g., polyurethane). As shown in FIGS. 1 through 10, this polyurethane body includes the handle 105 and the light cells 110 of spine 107 as described herein. The fabrication of the polyurethane body of the utility light 100 is described in more detail below.

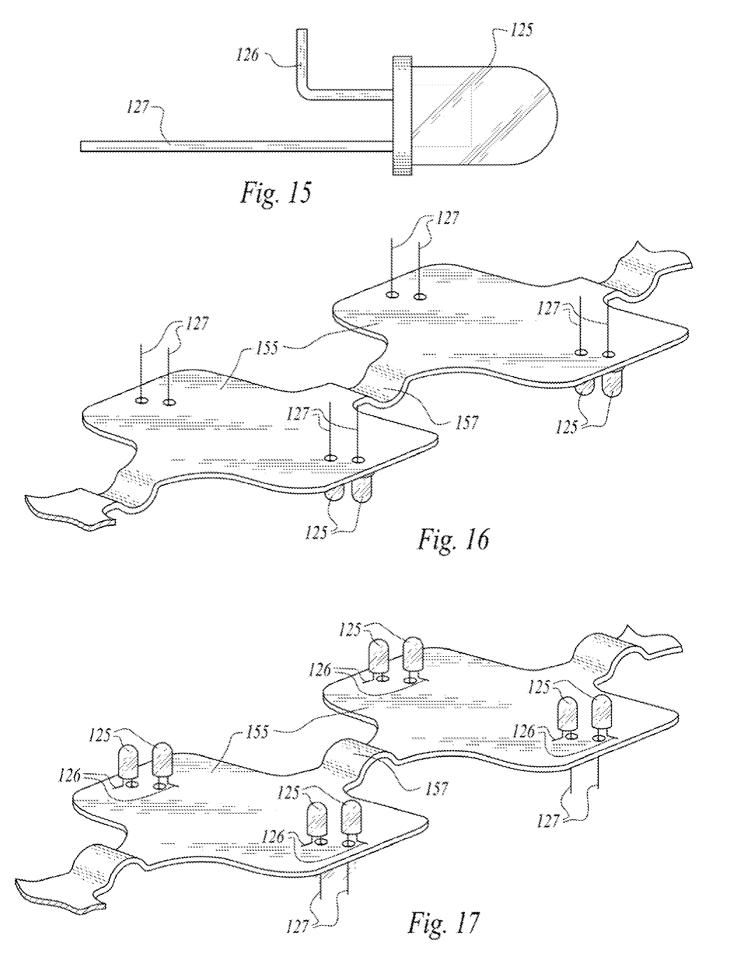

Referring again to FIG. 1, the electrical components of the utility light 100 include the LEDs 125, an electrical power source (e.g., a re-chargeable battery) 135, wires 137, 138, and 139, conducting plane 155, charging port 136, and switch 115. As described in more detail below, the re-chargeable battery 135 provides a re-chargeable and portable electrical power source for the utility light 100. In a particular embodiment, re-chargeable battery 135 can be a Lithium Ion 3.7V 2200 mAh battery with a battery housing 2 in. by 1.5 in, by 0.250 in., and with all terminals terminated on one end. It will be apparent to those of ordinary skill in the art that an alternative portable or wired electrical power source could also be used. A charging port and pigtail of one embodiment can include an 18/2 gauge wire, 2.5 MM input jack, and stainless jackets for implementation with charging port 136. In a particular embodiment, the LEDs can be ultra clear tip, 40000 mcd power, 5 mm tip, 20 degree viewing angle, 3.4-3.8 forward voltage, 20 MAh draw, and with solder leads. FIG. 15 illustrates an LED used in an example embodiment. In an alternative embodiment, each LED can be fitted with a reflective collar to improve and/or focus the light emitted by the LED. In a particular embodiment, the switch 115 can be a standard plunger-type panel-mounted push button ON/OFF electrical switch with a threaded collar for a 9 mm rubber tip, a 3 A contact rating, and dimensions of 1 in. by 0.530 in. by 0.690 in. tall. It will be apparent to those of ordinary skill in the art that other equivalent electrical power sources, charging ports, LEDs, and/or switches can be used.

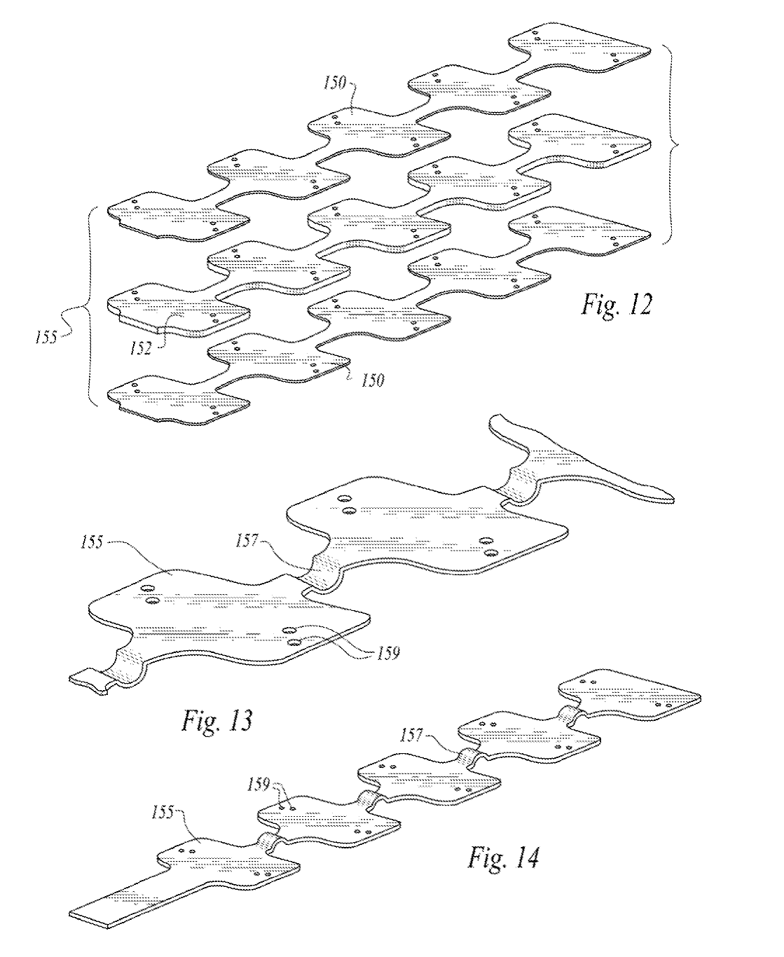

As described in more detail below, the conducting plane 155 is used to provide electrical conductivity and connection between the battery 135, switch 115, and LEDs 125. The conducting plane 155 can also serve to provide physical/mechanical reinforcement for the flexible or bendable rigidity of the articulated spine 107. As shown in FIG. 12, conducting plane 155 can be fabricated from three layers sandwiched together to form a single planar structure. The three layers of the conducting plane 155 include two electrical conducting layers 150, such as sheet copper, with a nonconducting layer 152 inserted between the two electrical conducting layers 150. The non-conducting layer 152 can be a pliable non-conductor, such as a plastic, cellophane, fabric, paper, or other non-conductive flexible material. The three layers can be bonded together using a spray adhesive, glue, or other form of bonding agent.

As shown in FIGS. 1-21 and described in more detail below, the electrical leads of each LED 125 are electrically connected (e.g., soldered) to each of the two conducting layers 150 of conducting plane 155. One electrical lead of each LED 125 is electrically connected to an upper conducting layer 150 and the other electrical lead of each LED 125 is electrically connected to a lower conducting layer 150 of conducting plane 155. The upper and lower conducting layers 150 can act as cathode and anode layers for the electrical system of the embodiments described herein. Additionally, each of the two conducting layers 150 of conducting plane 155 are electrically connected (e.g., soldered) to the switch 115 and battery 135 via wires 137, 138, and 139. One electrical lead 137 of battery 135 is electrically connected to the upper conducting layer 150 of conducting plane 155. Another electrical lead 138 of battery 135 is electrically connected to a contact of switch 115. Another electrical lead 139 is electrically connected between another contact of switch 115 and the lower conducting layer 150 of conducting plane 155. In this manner, the plurality of LEDs 125 is in switchable electrical connection with battery 135. Upon activation of the switch 115, electricity is enabled to flow from the battery 135 to the LEDs 125 via the conducting plane 155. As a result, the LEDs 125 are illuminated as shown in FIG. 6. Upon deactivation of the switch 115, electrical flow is disabled from the battery 135 to the LEDs 125 via the conducting plane 155. As a result, the light emitted from LEDs 125 is extinguished.

In an example embodiment, switch 115 is encapsulated in polyurethane as an anchoring point during the over-mold process, described in more detail below. The switch 115 is water, dirt, and chemical resistant (i.e., contamination resistant). The switch 115 includes an external rubber boot that protects internal components from liquids and debris. The switch 115 and the location of the switch 115 allow the utility light 100 to be conveniently used in submersed applications. The switch 115 also aids in the durability of the utility light 100. The switch 115 is located in an ergonomic location and is easy for the user to depress while using the handle 105 to hold the utility light 100.

A charging port 136 is provided to enable the recharging of battery 135. The charging port 136 is encapsulated in the polyurethane at the handle 105 of the utility light 100. The location and placement of the charging port 136 within the handle 105 protects the charging port 136 from contaminants and allows for easy charging. A receptacle end of the charging port 136 is exposed at an end of handle 105 to enable an electrical jack to be plugged into the receptacle end of the charging port 136 to charge battery 135. In an alternative embodiment, an inductive charging process can be used to charge battery 135. In this case, the charging port 136 may riot be needed.

In a particular embodiment shown in FIG. 3, magnets 120 are inserted on a back side of spine 107 during fabrication of the utility light 100. As shown, each light cell 110 can retain one or more magnets. In a particular embodiment, magnets 120 can be neodymium magnets of rare Earth material, 1 in. by 1 in. by 0.125 thick, with a 12.8 lb. pulling power. The magnets 120 serve to enable the utility light 100 to be temporarily attached to a metal surface. The magnets 120 enable the utility light 100 to adhere to metallic, surfaces in flat, concave, convex, and multi-angled shapes. The encapsulated magnets 120 also aid the user in the ability to reach and retrieve small, metal objects in a mechanical application. This vastly expands the utility of the tool and gives the operator options for hands free use. The utility light 100 only requires 60% of the magnets to touch a metallic surface to support the weight of the utility light 100. By encapsulating the magnets, they become protected from impact and provide a sleek, ergonomic feel.

In the example embodiments shown in FIGS. 1-21, the utility light 100 is fabricated from the combination of electrical components, described above, captured in to body comprising a flexible formed non-metallic material (e.g., polyurethane). As described in more detail below, the combination of electrical components can be arranged in a mold. Subsequently, liquefied polyurethane can be poured or injected into the mold and allowed to cure. Upon removal from the mold, the cured polyurethane provides a flexible and bendable yet rigid structure to serve as the body of utility light 100. The polyurethane insulates the combination of electrical components captured therein from electrical interference, moisture, dirt, or other contaminants, and physical impacts or pressures. In one embodiment, the polyurethane used can be a two-part, elastomeric polyurethane that can be mold ready and pourable or pressure injectable into a mold. The polyurethane can be clear or various colors can be added. In one embodiment, the utility light 100 is made with a clear and pigmented over-mold process. The colors added to the poured material can hide the internal components. The dark base colors also help to reflect light from the LED bases. Pigment added to the material also protects the internal components of the utility light 100 from damaging ultraviolet light.

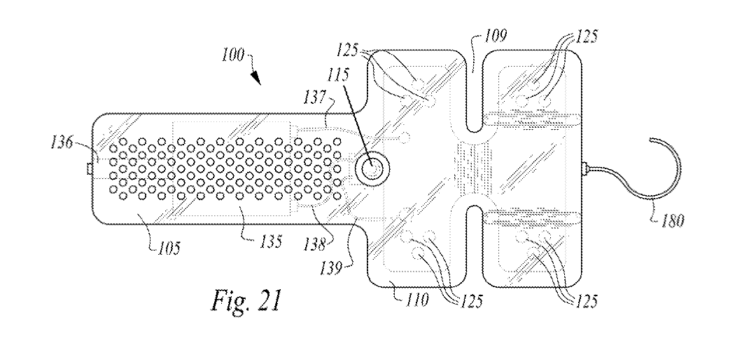

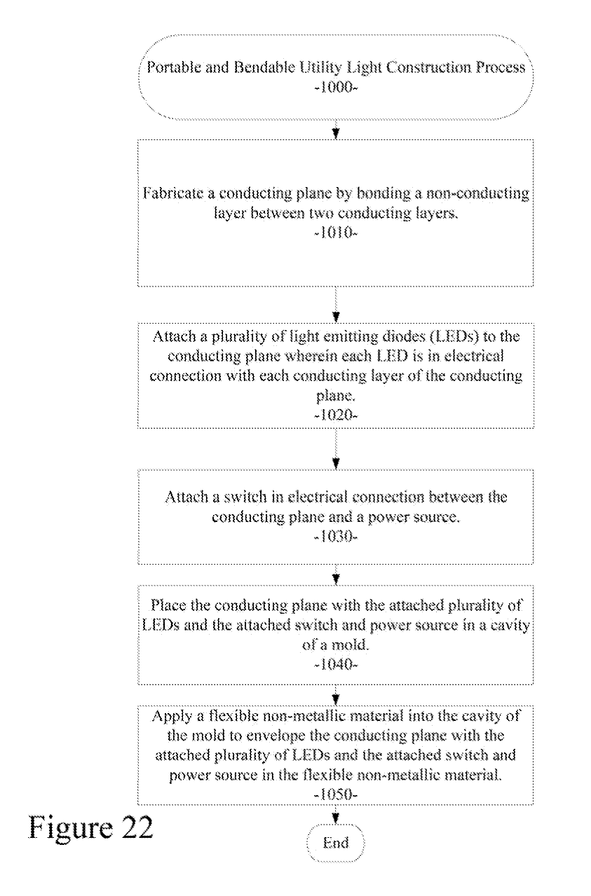

In a particular embodiment shown in FIG. 21, an integrated hook boss 180 can be provided at the end of spine 107 at the opposite end from handle 105. This integrated hook boss 180 allows the utility light 100 to be hung for hands-free lighting situations. For example, the integrated hook boss 180 can be used to hang the utility light 100 from a nail, a wire, or the like. As also illustrated in FIG. 21, the utility light 100 can be constructed in a variety of configurations. For example, FIG. 1 illustrates a utility light 100 with ten light cells 110 and two LEDs in each light cell 110. In the alternative embodiment shown in FIG. 21, a utility light 100 is illustrated with four light cells 110 and three LEDs in each light cell 110. It will be apparent to those of ordinary skill in the art that a variety of different configurations of the utility light 100 are possible, given the disclosure herein.

### Construction of an Example Embodiment

In an example embodiment, the utility light 100 can be constructed in a series or steps in a construction process. These steps for the example embodiment are illustrated in FIGS. 11-20 and described below. In general, the construction process includes fabrication of the conducting plane 155, insertion of the LEDs 125 into the conducting plane 155, attachment of the power source (e.g., battery) 135 and switch 115 to the conducting plane 155, placement of the assembled electrical components into a cavity of mold 160, applying a flexible non-metallic material (e.g., polyurethane) into the cavity of the mold 160 by pouring or injecting the polyurethane in one or more layers, and de-molding the completed utility light 100.

Referring now to FIG. 11, a die press 170 is illustrated. The die press 170 can be used with die 172 to cut conducting layers 150 from a sheet of conductive material 174, such as copper. Similarly, die press 170 can be used with die 172 to cut non-conducting layer 152 from a sheet of non-conductive material, such as plastic, cellophane, fabric, paper, or other non-conductive flexible material. The die 172 is fabricated with a pattern corresponding to the shape of the conducting plane 155 shown in FIG. 12. This shape includes an outline of the handle 105 portion of the body and an outline of the plurality of light cells 110. The shape of die 172 also defines the radiused gaps 109 between light cells 110. The die 172 can also include pointed portions to pierce holes for a solder lead for each of the LEDs 125. Using well-known techniques, the die press 170, or some equivalent thereof, may be used to cut or stamp out two electrical conducting layers 150 and a non-conducting layer 152 as shown in FIG. 12.

Referring now to FIG. 12, the two electrical conducting layers 150 and a non-conducting layer 152 are stacked or sandwiched together to form a three-layered conducting plane 155. The two electrical conducting layers 150 and the non-conducting layer 152 can be bonded together using an adhesive spray, glue, or other conventional bonding technique. As a result, a layered conducting, plane 155 is produced. The layered conducting plane 155 includes an upper conducting layer and a lower conducting layer. Each conducting layer is electrically isolated or insulated from the other layer.

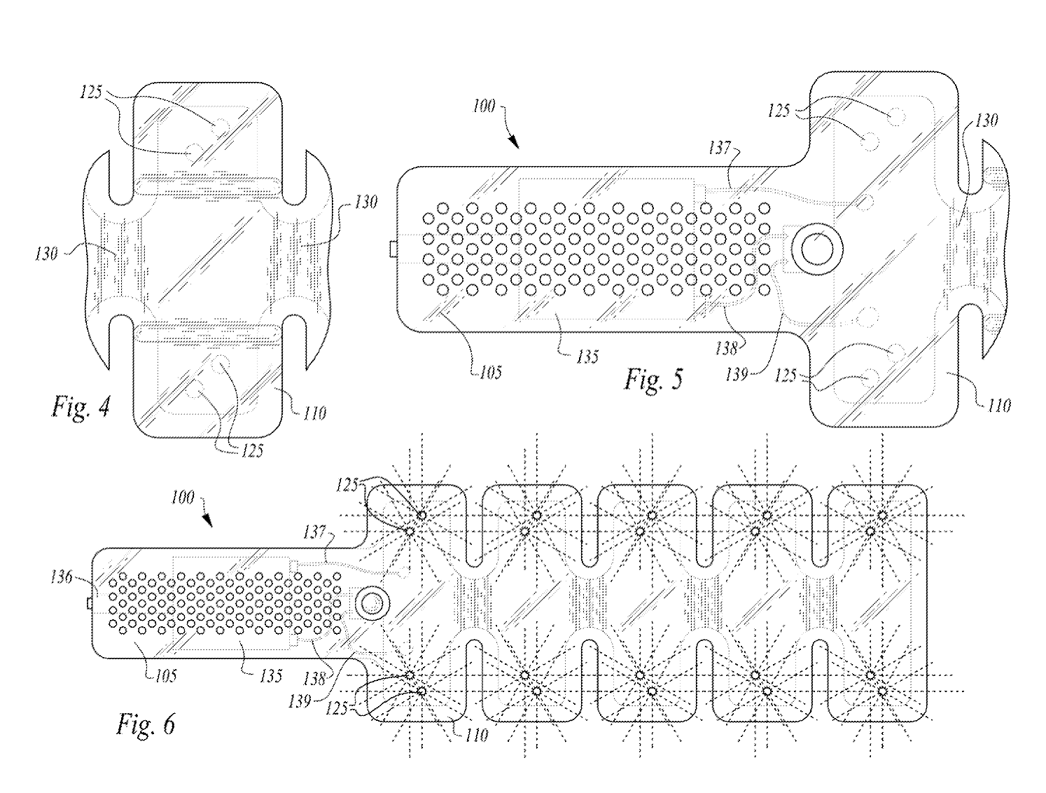

Referring now to FIG. 13, the layered conducting plane 155 can be modified to include a depression at each joint 157 between each of the plurality of light cells 110. The depression at each joint 157 serves to strengthen the joint by more evenly spreading the forces when the spine 107 is bent or rotated. The depression of the conducting plane 155 at each joint 157 thereby facilitates the bending or rotating of the spine 107 and resists potential cracking or breakage of the conducting plane 155 at joint 157. Once the joints 157 of the conducting plane 155 are enveloped by polyurethane as described in detail below, the joints 130 between each light cell 110, as shown in FIG. 4, are able to withstand a high level of bending and twisting.

Referring now to FIG. 14, a completed conducting, plane 155 of an example embodiment is shown. The plurality of LEDs 125 can be electrically attached to the conducting plane 155 at as plurality of holes 159 in a next series of steps in the construction process of an example embodiment.

Referring now to FIGS. 15-17, an example embodiment illustrates how a plurality of LEDs 125 can be electrically attached to the conducting plane 155 at a plurality of holes 159. In one embodiment, each LED 125 can include two electrical solder leads as shown in FIG. 15. A first solder lead 126 can be electrically attached (e.g., soldered) to an upper layer of conducting plane 155 as shown in FIG. 17. A second solder lead 127 of LED 125 can be inserted through each of holes 159 and electrically attached (e.g., soldered) to a lower layer of conducting plane 155 as shown in FIG. 16. In this manner, each of the LEDs 125 can be electrically attached to the conducting plane 155 at locations corresponding to the light cells 110 of spine 107. For each of the attached LEDs 125, one electrical lead is electrically connected to an upper layer of conducting plane 155 and one electrical lead is electrically connected to a lower layer of conducting plane 155. As such, electrical continuity exists between each of the LEDs 125 and the conducting plane 155. It will be apparent to those of ordinary skill in the art that in an alternative embodiment, conventional printed circuit board manufacturing techniques can be employed to fabricate a conducting plane 155 with as plurality of LEDs 125 attached thereto in a manner consistent with the disclosure provided herein. Furthermore, it will be apparent to those of ordinary skill in the art that in alternative embodiments, one or more LEDs 125 can be attached to the light cell 110 portions of the conducting plane 155. Additionally, it will be apparent to those of ordinary skill in the art that in alternative embodiments, a particular utility light 100 can have two or more light cells 110 arranged on a spine 107.

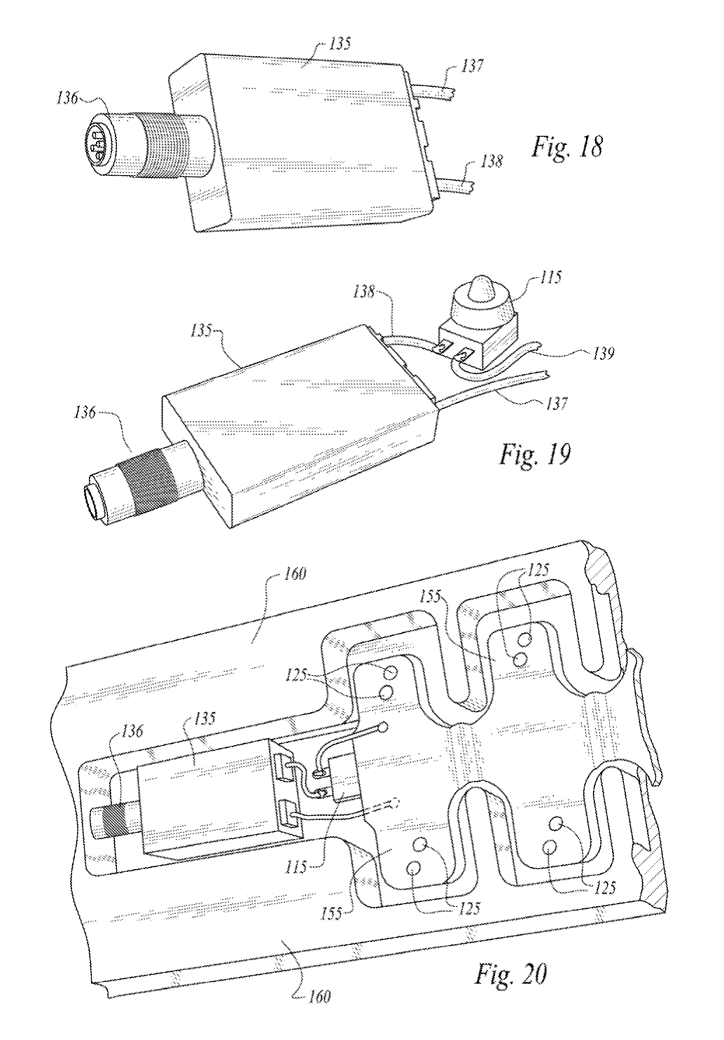

Referring now to FIGS. 1 and 18-19, an example embodiment illustrates how power source (e.g., battery) 135 and switch 115 are electrically connected to the conducting plane 155 with as plurality of LEDs 125 attached thereto. As shown in FIG. 18, battery 135 can include a charging port 136 and two electrical connection leads 137 and 138. As shown in FIGS. 1 and 19, a first electrical connection lead 137 can be electrically attached (e.g., soldered) to the upper layer of conducting plane 155. A second electrical connection lead 138 can be electrically attached (e.g., soldered) to a first contact of switch 115. A third electrical connection lead 139 can be electrically attached (e.g., soldered) to a second contact of switch 115 and to the lower layer of conducting plane 155. In this manner, electrical continuity exists between the battery 135, the switch 115, each of the LEDs 125, and the conducting plane 155. As a result, the plurality of LEDs 125 is in switchable electrical connection with battery 135. It will be apparent to those of ordinary skill in the art that in an alternative embodiment, battery 135 can be a set of two or more batteries in a stacked or linear arrangement with electrical continuity between each of the batteries of the set. A plurality of batteries in a set can provide more power for the LEDs 125, if more power is needed. Furthermore, it will be apparent to those of ordinary skill in the art that in alternative embodiments, switch 115 can be any of a variety of conventional switches, such as plunger-type switches, slide switches, toggle switches, and the like. Once the battery 135 and switch 115 are electrically connected to the conducting plane 155 as described above in an example embodiment, the assembly of the electrical components of the utility light 100 is complete. The completed electrical assembly can be placed into a cavity of mold 160 for application of the polyurethane as shown in FIG. 20 and described in detail below.

Referring now to FIG. 20, an example embodiment illustrates the application of polyurethane to an electrical assembly positioned in a mold, in an example embodiment. The mold 160 can be an aluminum mold with a cavity that defines the shape of the body of the utility light 100, including the handle 105 and light cells 110 of the utility light 100. The shape of the cavity of mold 160 also defines the radiused gaps 109 between light cells 110. The completed electrical assembly can be placed top-down (inverted) into the cavity of mold 160. The placement of the electrical assembly in the cavity of mold 160 is such that an can portion of charging port 136 and the top of switch 115 are not exposed to the polyurethane. As a result, the end portion of charging port 136 and the top of switch 115 are the only two elements of the electrical assembly that are externally exposed and not enveloped by polyurethane as pan of the construction process.

In a particular embodiment, the polyurethane can be added to the cavity of mold 160 in three applications. In as first application, a clear (color-absent) polyurethane is added to the cavity of mold 160 by pouring or by injection. Because the electrical assembly is placed top-down (inverted) into the cavity of mold 160, the first application of clear polyurethane envelopes the plurality of LEDs 125 in clear polyurethane. The clear polyurethane enables the light emitted by the LEDs 125 to shine through the clear polyurethane without a significant loss of lumens. The first application of polyurethane can be allowed to cure. In a second application, a colored polyurethane can be added to the cavity of mold 160 by pouring or by injection. The colored polyurethane is added as a second layer on top of the clear polyurethane layer. The colored polyurethane layer envelopes the conducting plane 155, the base of switch 115, battery 135, and charging port 136 in colored polyurethane. In an alternative embodiment, the battery 135 can be added after testing is performed to confirm the proper operation of all LEDs 125 and switch 115. The second application of polyurethane can be allowed to cure. When the second application of polyurethane cures to a desired point, the plurality of magnets 120 can be placed into mold 160 on top of the second layer of polyurethane in positions corresponding to each light cell 110 as shown in FIG. 3. At this point, all utility light 100 components have been installed in the construction process. The mold 160 can be covered with a clamshell-type cover and the remaining polyurethane can be injected into the closed mold 160 in a third application of polyurethane. The injected polyurethane covers the magnets 120 and completes the back side of the utility light 100. When the third application of polyurethane cures, the cover of mold 160 can be removed and the completed utility light 100 can be removed from the mold 160. Thus, a utility light 100 as described herein can be constructed using the processes described herein.

The illustrations of embodiments described herein are intended to provide a general understanding of the structure of various embodiments, and they are not intended to serve as a complete description of all the elements and features of apparatus and systems that might make use of the structures described herein. Many other embodiments will be apparent to those of ordinary skill in the art upon reviewing the above description. Other embodiments may be utilized and derived therefrom, such that structural and logical substitutions and changes may be made without departing from the scope of this disclosure. The figures provided herein are merely representational and may not be drawn to scale. Certain proportions thereof may be exaggerated, while others may be minimized. Accordingly, the specification and drawings are to be regarded in an illustrative rather than a restrictive sense.

The description herein may include terms, such as “up”, “down”, “upper”, “lower”, “first”, “second”, etc. that are used for descriptive purposes only and are not to be construed as limiting. The elements, materials, geometries, dimensions, and sequence of operations may all be varied to suit particular applications. Pans of some embodiments may be included in or substituted for, those of other embodiments. While the foregoing examples of dimensions and ranges are considered typical, the various embodiments are not limited to such dimensions or ranges.

The Abstract is provided to comply with 37 C.F.R. §1.74(b) to allow the reader to quickly ascertain the nature and gist of the technical disclosure. The Abstract is submitted with the understanding that it will not be used to interpret or limit the scope or meaning, of the claims.

In the foregoing Detailed Description, various features are grouped together in a single embodiment for the purpose of streamlining the disclosure. This method of disclosure is not to be interpreted as reflecting an intention that the claimed embodiments have more features than are expressly recited in each claim. Thus, the following claims are hereby incorporated into the Detailed Description, with each claim standing on its own as a separate embodiment.

Thus, a portable and bendable utility light is disclosed. While the present invention has been described in terms of several example embodiments, those of ordinary skill in the art can recognize that the present invention is not limited to the embodiments described, but can be practiced with modification and alteration within the spirit and scope of the appended claims. The description herein is thus to be regarded as illustrative instead of limiting.

What is claimed is:

1. A portable and bendable utility light comprising:
a body fabricated from a flexible non-metallic material, the body including a spine and a handle, the spine including a plurality of articulated light cells and corresponding radiused gaps between each light cell to facilitate bending of the spine in a plurality of directions; and
an electrical assembly enveloped within the body, the electrical assembly including a conducting plane, a plurality of light emitting diodes (LEDs) in electrical connection with the conducting plane and positioned within each of the plurality of articulated light cells, a power source in electrical connection with the conducting plane, and a switch in electrical connection with the power source and the conducting plane.

2. The portable and bendable utility light as claimed in claim 1 wherein the flexible non-metallic material is polyurethane.

3. The portable and bendable utility light as claimed in claim 1 wherein the body includes a plurality of magnets enveloped therein.

4. The portable and bendable utility light as claimed in claim 1 wherein the power source is a re-chargeable battery and the electrical assembly includes a charging port in electrical connection with the battery.

5. The portable and bendable Utility light as claimed in claim 1 wherein the flexible non-metallic material is polyurethane and the body includes a clear transparent layer of polyurethane and a colored layer of polyurethane.

6. The portable and bendable utility light as claimed in claim 1 wherein the conducting plane includes a cathode layer and an anode layer.

7. The portable and bendable utility light as claimed in claim 1 wherein the switch is contamination resistant.

8. The portable and bendable utility light as claimed in claim 1 wherein the power source is enveloped in the handle portion of the body.

9. An apparatus comprising:
a body means fabricated from a flexible non-metallic material, the body means including a spine means and a handle means, the spine means including a plurality of articulated light cells and corresponding radiused gaps between each light, cell to facilitate bending of the spine means in a plurality of directions; and
an electrical assembly means enveloped within the body means, the electrical assembly means including a conducting plane, a plurality of light emitting diodes (LEDs) in electrical connection with the conducting plane and positioned within each of the plurality of articulated light cells, a power source in electrical connection with the conducting plane, and a switch in electrical connection with the power source and the conducting plane.

10. The apparatus as claimed in claim 9 wherein the flexible non-metallic material is polyurethane.

11. A method comprising:
fabricating a conducting plane by bonding a non-conducting layer between two conducting layers;
attaching a plurality of light emitting diodes (LEDs) to the conducting plane wherein each LED is in electrical connection with each conducting layer of the conducting plane;
attaching a switch in electrical connection between the conducting plane and a power source;
placing the conducting plane with the attached plurality of LEDs and the attached switch and power source in a cavity of a mold; and
applying a flexible non-metallic material into the cavity of the mold to envelope the conducting plane with the attached plurality of LEDs and the attached switch and power source in the flexible non-metallic material.

12. The method as claimed in claim 11 wherein the flexible non-metallic material is polyurethane.

13. The method as claimed in claim 11 including placing a plurality of magnets into the cavity of the mold, the plurality of magnets being enveloped by the flexible non-metallic material.

14. The method as claimed in claim 11 wherein the power source is a re-chargeable battery, the method including attaching a charging port to the battery, the charging port being in electrical connection with the battery, the charging port being enveloped by the flexible non-metallic material.

15. The method as claimed in claim 11 wherein the flexible non-metallic material is polyurethane applied in a clear transparent layer of polyurethane and a colored layer of polyurethane.

16. The method as claimed in claim 11 wherein the conducting plane includes a cathode layer and an anode layer.

17. The method as claimed in claim 11 wherein the switch is contamination resistant.

18. The method as claimed in claim 11 wherein the flexible non-metallic material is applied into the cavity of the mold by pouring the flexible non-metallic material.

19. The method as claimed in claim 11 wherein the flexible non-metallic material is applied into the cavity of the mold by an injection process.
